(19) United States
(12) Patent Application Publication
(10) Pub. No.: US 2026/0237426 A1
(43) Pub. Date: Aug. 13, 2026

(54) SEMICONDUCTOR MEMORY DEVICE, OPERATING METHOD THEREOF, AND ELECTRONIC SYSTEM INCLUDING THE SEMICONDUCTOR MEMORY DEVICE

(71) Applicants: Samsung Electronics Co., Ltd., Suwon-si (KR); SEOUL NATIONAL UNIVERSITY R&DB FOUNDATION, Seoul (KR)

(72) Inventors: Sangbum KIM, Seoul (KR); Hyeongjun SEO, Seoul (KR); Kanghyeon BYUN, Seoul (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 19/455,091

(22) Filed: Jan. 21, 2026

(30) Foreign Application Priority Data
Feb. 11, 2025 (KR) 10-2025-0017566
Mar. 6, 2025 (KR) 10-2025-0029201

(51) Int. Cl. G11C 11/4096; G11C 11/4074; G11C 15/04

(52) U.S. Cl. CPC G11C 11/4096; G11C 11/4074; G11C 15/04

(57) ABSTRACT

A semiconductor memory device includes a ternary content-addressable memory (TCAM) array including a plurality of TCAM cells each including two dynamic random-access memory (DRAM) cells and a logic circuit, and a peripheral circuit configured to control an operation of the TCAM array. Each of the two DRAM cells includes an access transistor and a storage capacitor, wherein the logic circuit is configured to operate in response to a power supply voltage and output, to an output node, a voltage corresponding to a result of an exclusive OR (XOR) operation between search data corresponding to a voltage applied to a select line and stored data stored in the storage capacitor. The output node of each of the plurality of TCAM cells may be connected to a match line through a respective output capacitor.

### CROSS-REFERENCE TO RELATED APPLICATIONS

This application is based on and claims priority under 35 U.S.C. § 119 to Korean Patent Application Nos. 10-2025-0017566, filed on Feb. 11, 2025, and 10-2025-0029201, filed on Mar. 6, 2025, in the Korean Intellectual Property Office, the disclosures of which are incorporated by reference herein in their entirety.

### BACKGROUND

### 1. Field

The disclosure relates to a semiconductor memory device, an operating method thereof, and an electronic system including the semiconductor memory device.

### 2. Description of the Related Art

In some memory (e.g., dynamic random-access memory (DRAM), static random-access memory (SRAM), etc.), each memory cell is assigned a unique address and access to data is made based on the address when reading or writing data, whereas content addressable memory (CAM) performs searches based on data itself, not the address thereof. CAM based on the content-based approach may simultaneously retrieve specific data from the entire memory cell when performing a search.

CAM generally stores only binary values of 0 or 1, whereas ternary content addressable memory (TCAM) stores ternary values of 0, 1, or X (“don't care”). The term “don't care” means that any value is acceptable, and thus, any particular bit is treated as a match regardless of whether it is 0 or 1. Thus, TCAM may perform a more flexible and complex search than CAM. TCAM has been mainly used in network equipment such as routers, switches, and cache memory, but may have other applications. However, since TCAM is more expensive and consumes more power than CAM, a technology for providing lower-cost, lower-power TCAM may be beneficial.

### SUMMARY

Provided are a semiconductor memory device, an operating method thereof, and an electronic system including the semiconductor memory device. Specifically, various example embodiments are intended to provide a semiconductor memory device including a lower-cost, lower-power TCAM array that supports higher-speed parallel operations while ensuring data integrity, an operating method thereof, and an electronic system including the semiconductor memory device. The technical problem to be achieved by the disclosure is not limited to the technical problems as described above, and other technical problems may be inferred from the following example embodiments.

Additional aspects will be set forth in part in the description which follows and, in part, will be apparent from the description, or may be learned by practice of the presented example embodiments of the disclosure.

According to an aspect of the disclosure, a semiconductor memory device comprises a ternary content-addressable memory (TCAM) array including a plurality of TCAM cells, each including two dynamic random-access memory (DRAM) cells and a logic circuit, and a peripheral circuit configured to control an operation of the TCAM array, wherein each of the two DRAM cells comprises an access transistor including a gate connected to a word line, a drain connected to a bit line, and a source connected to a storage node, and a storage capacitor connected to the storage node, wherein the logic circuit is configured to operate in response to a power supply voltage and to output, to an output node, a voltage corresponding to a result of an exclusive OR (XOR) operation between search data corresponding to a voltage applied to a select line and stored data stored in the storage capacitor, and the output node of each of the plurality of TCAM cells may be connected to a match line through a respective output capacitor.

According to another aspect of the disclosure, an operating method of a semiconductor memory device, which comprises a ternary content-addressable memory (TCAM) array including a plurality of TCAM cells, each including two dynamic random-access memory (DRAM) cells and a logic circuit, and a peripheral circuit configured to control an operation of the TCAM array, the operating method including charging an output node with a power supply voltage by connecting, to ground, a match line connected to the output node of the logic circuit corresponding to each of the plurality of TCAM cells through a respective output capacitor, and a select line used to apply a voltage corresponding to search data, floating the match line, and by applying the voltage corresponding to the search data to the select line, outputting, to the output node, a voltage corresponding to a result of an exclusive OR (XOR) operation between the search data and stored data stored in the two DRAM cells.

According to another aspect of the disclosure, an electronic system comprises a semiconductor memory device, a processor configured to process data search and comparison operations in parallel using the semiconductor memory device, wherein the semiconductor memory device comprises a ternary content-addressable memory (TCAM) array including a plurality of TCAM cells, each including two dynamic random-access memory (DRAM) cells and a logic circuit, and a peripheral circuit configured to control an operation of the TCAM array, wherein each of the two DRAM cells comprises an access transistor including a gate connected to a word line, a drain connected to a bit line, and a source connected to a storage node, and a storage capacitor connected to the storage node, wherein the logic circuit is configured to operate in response to a power supply voltage and output, to an output node, a voltage corresponding to a result of an exclusive OR (XOR) operation between search data corresponding to a voltage applied to a select line and stored data stored in the storage capacitor, the output node of each of the plurality of TCAM cells is connected to a match line through a respective output capacitor, and a voltage level of the match line is related to a number of matching bits between the search data and the stored data.

### BRIEF DESCRIPTION OF THE DRAWINGS

The above and other aspects, features and advantages of certain example embodiments of the disclosure will be more apparent from the following description taken in conjunction with the accompanying drawings, in which:

FIG. 1 shows diagrams for explaining an operating principle of ternary content-addressable memory (TCAM);

FIG. 2 is a circuit diagram illustrating a configuration of a TCAM array according to example embodiments;

FIG. 3 shows diagrams for explaining a hold operation of a TCAM array according to example embodiments;

FIG. 4 shows diagrams for explaining a read operation of a TCAM array according to example embodiments;

FIG. 5 shows diagrams for explaining a write or refresh operation of a TCAM array according to example embodiments;

FIGS. 6A to 6C show diagrams for explaining a search operation of a TCAM array according to example embodiments;

FIG. 7 is a table diagram illustrating a truth table during a search operation of a TCAM array according to example embodiments;

FIG. 8 is a circuit diagram illustrating a configuration of a TCAM array according to example embodiments;

FIG. 9 is a block diagram illustrating a semiconductor memory device according to example embodiments;

FIG. 10 is a flowchart illustrating an operating method of a semiconductor memory device according to example embodiments; and

FIG. 11 is a block diagram illustrating a configuration of an electronic system according to example embodiments.

### DETAILED DESCRIPTION

Reference will now be made in detail to example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terms used in the present example embodiments as widely as possible are selected while considering the functions in the present example embodiments, but this may vary depending on the intention or precedent of an ordinary skill in the art, the emergence of a new technology, and the like. In addition, in certain cases, there are arbitrarily selected terms, and in this case, the meaning will be described in detail in the description of the relevant example embodiments. Therefore, the terms used in the present example embodiments should be defined based on the meanings of the terms and the overall descriptions of the present example embodiments, not just the names of the terms.

In the descriptions of the example embodiments, when a part is connected to another part, it includes not only a case in which the former is directly connected to the latter, but also a case in which the former is electrically connected to the latter with another component therebetween. In addition, when a part “includes” a component, this means that the part may further include other components, not excluding other components unless otherwise stated.

Terms such as “have” or “include” used in the present example embodiments should not necessarily be construed as including all of the various components described in the disclosure, and some of the components or some of the operations or steps may not be included, or may further include additional components or operations or steps.

In addition, terms including ordinal numbers, such as “first” or “second” used in this disclosure, may be used to describe various components, but the above components should not be limited by the above terms. The terms are used only for the purpose of distinguishing one component from another.

The description of the following example embodiments should not be construed as limiting the scope of rights, and what those skilled in the art may easily infer should be construed as belonging to the scope of rights of the example embodiments. Hereinafter, example embodiments solely for illustration will be described in detail with reference to the accompanying drawings.

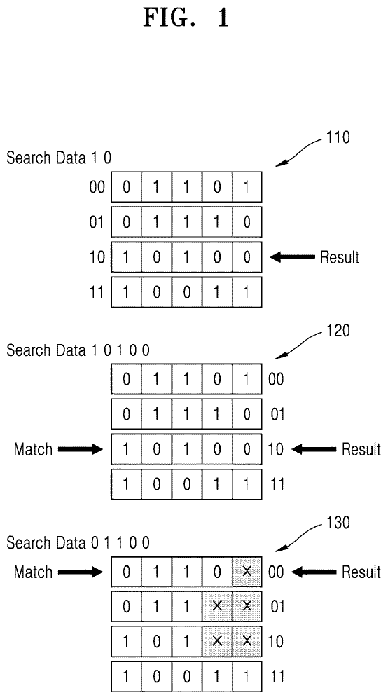

FIG. 1 shows diagrams for explaining an operating principle of ternary content-addressable memory (TCAM);

Referring to FIG. 1, lookup tables 110, 120, and 130 for comparing the operating principles of regular memories (e.g., DRAM, SRAM, etc.), CAM, and TCAM are shown.

According to the lookup table 110, it may be seen that the regular memory uses an address value to find stored data. For example, the regular memory uses an address value 10100 to search the stored data 10. In other words, the regular memory may find a result value of 10100 by using the search data 10.

In contrast, according to the lookup table 120, it may be seen that CAM finds an address value or a stored location by using data. For example, the CAM may find the stored data 10100 by using the search data 10100.

In addition to the operating principle of the CAM, TCAM extends the bit value of stored data to 1, 0, and X (here, X is don't care). The bit X is a bit that causes the search data bit to be matched regardless of whether it is 1 or 0. According to the lookup table 130, it may be seen that data 0110X (here, X is don't care) stored for the search data 01100 may be searched as a match vector. When a plurality of match vectors exist, a specific match vector may be selected according to a preset priority rule. The TCAM may search all of the stored data in parallel to search for match vectors matching the search data.

Thus, the TCAM may perform more flexible and/or complex search than the CAM. The TCAM may be used in network equipment such as routers, switches, and cache memory, and also may be increasingly useful in artificial intelligence (AI)-oriented devices that require larger-capacity memory and/or higher-speed search. However, since the TCAM is more expensive and consumes more power than the CAM, a technology for providing a lower-cost, lower-power TCAM would be beneficial.

For example, the TCAM according to a conventional technology used two static random-access memories (SRAMs) as bit cells that store 1-bit data, respectively. However, each SRAM includes six transistors, and SRAM-based TCAM consists of 16 transistors, and thus, the required area is larger, and the process difficulty and/or cost are higher. In addition, the SRAM is a volatile memory that should always be powered to store data, and thus, it consumes a lot of power.

According to another conventional technology, attempts have been made to reduce the overall area by using fewer transistors or to reduce the power consumption of a TCAM by using non-volatile bit cells or near-non-volatile bit cells. However, in such conventional technology, because the variation of devices used as bit cells is larger than the SRAM, resolution degradation has occurred when producing an array containing a large number of bit cells. Therefore, it was difficult for conventional technology to be used for AI-oriented TCAM applications such as large language models (LLMs), which require arrays containing a large number of bit cells.

Various example embodiments of the present disclosure are to provide a lower-cost, lower-power TCAM array that supports higher-speed parallel operations while ensuring data integrity by reducing or preventing resolution degradation. Hereinafter, a TCAM array according to the present inventive concepts will be described in detail with reference to the drawings.

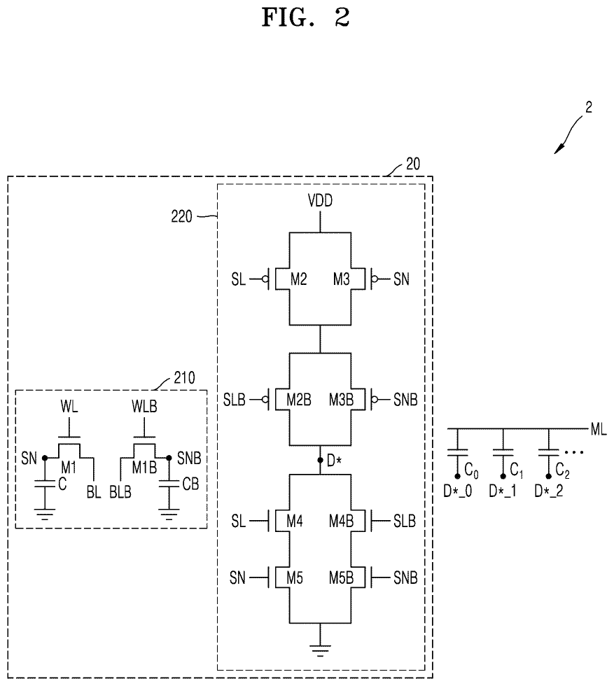

FIG. 2 is a circuit diagram illustrating a configuration of a TCAM array according to example embodiments.

Referring to FIG. 2, a TCAM array 2 may include a plurality of TCAM cells 20, each including two DRAM cells 210 and a logic circuit 220. In addition, the TCAM array 2 may include output capacitors (C_{O}, C₁, C₂, . . . ) connected between each TCAM cell 20 and a match line ML. In other words, the output node (one of D*_0, D*_1, D*_2, . . . ) of each of the plurality of TCAM cells 20 may be connected to the match line ML through the respective output capacitor (one of C_{O}, C₁, C₂, . . . ). In FIG. 2, only one TCAM cell 20 is represented as a representative example, but the TCAM array 2 may include TCAM cells 20 corresponding to the output nodes (D*_0, D*_1, D*_2, . . . ) and the output capacitors (C_{O}, C₁, C₂, . . . ), respectively.

Each of the two DRAM cells 210 may include an access transistor M1 or M1B including a gate connected to a word line WL or WLB, a drain connected to a bit line BL or BLB, and a source connected to a storage node SN or SNB, and a storage capacitor C or CB connected to the storage node SN or SNB.

The access transistor M1 or M1B may include an indium gallium zinc oxide (IGZO) thin film transistor (TFT). The IGZO TFT has a lower leakage current than a silicon-based transistor (e.g., a complementary metal-oxide-semiconductor (CMOS)). Therefore, the IGZO TFT-based DRAM does not need to perform refresh more often than the conventional DRAM, and may operate close to non-volatile. The IGZO TFT-based DRAM may operate close to non-volatile and may have better cycling durability than bit cells using conventional non-volatile memory (e.g., resistive random-access memory (RRAM) and ferroelectric random-access memory (FeRAM), etc.).

In addition, the IGZO TFT-based DRAM may require a smaller area compared to SRAM, enabling higher integration and/or scaling, and lower power consumption. Therefore, the IGZO TFT-based DRAM may be used to store a larger number of bits due to its higher integration and lower power characteristics.

The logic circuit 220 is a circuit for performing comparison between search data and stored data, and may be implemented as a logic gate. For example, the logic circuit 220 may be configured to operate by a power supply voltage VDD and output, to the output node D*, a voltage corresponding to a result of an exclusive OR (XOR) operation between the search data corresponding to the voltage applied to the select line SL or SLB and the stored data stored in the storage capacitor C or CB.

Since the power supply voltage VDD corresponding to a constant voltage source directly drives the signal, the logic circuit 220 may operate at a higher speed than the conventional TCAM that has been performing a search operation after precharging the match line, and may allow integrity-preserving transmission of data. Furthermore, even if an array containing a large number of TCAM cells 20 is manufactured, resolution degradation may be reduced or prevented due to the logic circuit 220. Therefore, the TCAM array 2 according to the present disclosure may be suitable for use in AI-oriented devices requiring larger-capacity memory and/or higher-speed search.

In some example embodiments, the logic circuit 220 may include first to fourth P-type metal-oxide-semiconductor (PMOS) transistors M2, M3, M2B and M3B and first to fourth N-type metal-oxide-semiconductor (NMOS) transistors M4, M4B, M5 and M5B. Sources of the first PMOS transistor M2 and the second PMOS transistor M3 may be connected to the power supply voltage VDD, and drains of the first PMOS transistor M2 and the second PMOS transistor M3 may be connected to sources of the third PMOS transistor M2B and the fourth PMOS transistor M3B.

Drains of the third PMOS transistor M2B and the fourth PMOS transistor M3B and drains of the first NMOS transistor M4 and the second NMOS transistor M4B may be connected to the output node D*. A source of the first NMOS transistor M4 may be connected to the drain of the third NMOS transistor M5, a source of the second NMOS transistor M4B may be connected to the drain of the fourth NMOS transistor M5B, and sources of the third NMOS transistor M5 and the fourth NMOS transistor M5B may be connected to a ground.

When the two DRAM cells 210 include a first DRAM cell and a second DRAM cell, gates of the first PMOS transistor M2 and the first NMOS transistor M4 may be connected to a first select line SL of the first DRAM cell, and gates of the second PMOS transistor M3 and the third NMOS transistor M5 may be connected to a first storage node SN of the first DRAM cell. In addition, gates of the third PMOS transistor M2B and the second NMOS transistor M4B may be connected to a second select line SLB of the second DRAM cell, and gates of the fourth PMOS transistor M3B and the fourth NMOS transistor M5B may be connected to a second storage node SNB of the second DRAM cell.

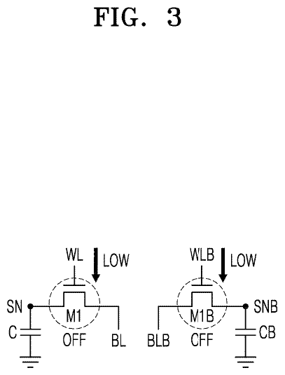

However, the configuration of the logic circuit 220 shown in FIG. 2 corresponds to the most basic implementation of the XOR logic gate, and the logic circuit 220 may be designed in other ways. For example, the logic circuit 220 may be configured to perform XOR operations based on logic design using only NAND gates, logic design using only NOR gates, exclusive NOR (XNOR) logic design, etc. Hereinafter, the operation of the TCAM array 2 according to the present disclosure will be described in more detail with reference to FIGS. 3 to 6C.

FIG. 3 shows diagrams for explaining a hold operation of a TCAM array according to example embodiments.

Referring to FIG. 3, a process of performing a hold operation of a DRAM cell included in a TCAM array (e.g., the TCAM array 2 of FIG. 2) is illustrated. When a low signal LOW is applied to a word line WL or WLB, the access transistor M1 or M1B is turned off, and a charge (e.g., stored data) stored in the storage capacitor C or CB is maintained as is. In example embodiments, the low signal LOW may mean a voltage level lower than a threshold voltage of the access transistor M1 or M1B.

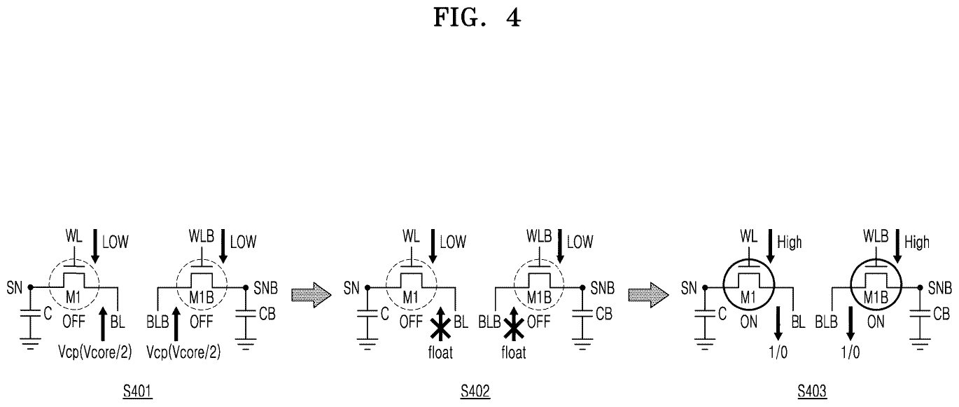

FIG. 4 shows diagrams for explaining a read operation of a TCAM array according to example embodiments.

Referring to FIG. 4, a process of performing a read operation of a DRAM cell included in a TCAM array (e.g., the TCAM array 2 of FIG. 2) is illustrated.

In operation S401, the bit line BL or BLB may be precharged to a voltage of Vcp. In an example, Vcp may be set to an intermediate value (e.g., Vcore/2) of Vcore corresponding to a power supply voltage of the DRAM. Vcp may correspond to a reference voltage for accurately detecting a voltage change that may occur when reading logical “0” or “1” of data.

In operation S402, the bit line BL or BLB may be floated as power supply is cut off. The access transistor M1 or M1B may be turned off until the bit line BL or BLB is in a floating state.

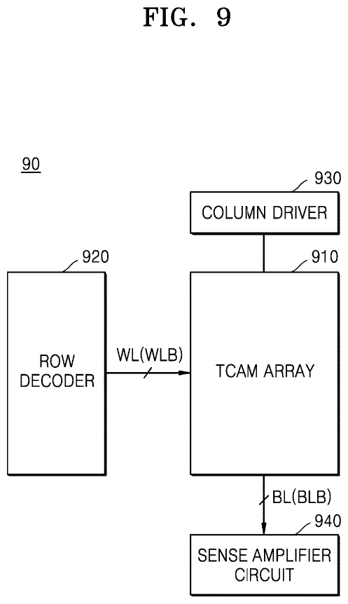

In operation S403, as a high signal HIGH is applied to the word line WL or WLB, the access transistor M1 or M1B may be turned on. In example embodiments, the high signal HIGH may mean a voltage level higher than the threshold voltage of the access transistor M1 or M1B. As the access transistor M1 or M1B is turned on, the voltage of the bit line BL or BLB may be changed, and this voltage change may be amplified by a sense amplifier circuit (e.g., a sense amplifier circuit 940 of FIG. 9). Data (e.g., 1 or 0) stored in the storage capacitor C or CB may be read based on the signal amplified by the sense amplifier circuit.

Data stored in each of the two DRAM cells may be read individually using each bit line BL or BLB, and two pieces of bit data may be read at once based on a voltage difference between the bit lines BL and BLB. After the read operation is completed, the DRAM cell may return to the hold operation. In addition, a refresh operation may be performed before the DRAM cell returns to the hold operation.

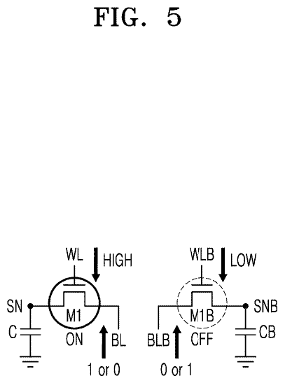

FIG. 5 shows diagrams for explaining a write or refresh operation of a TCAM array according to example embodiments.

Referring to FIG. 5, a process of performing a write or refresh operation of a DRAM cell included in a TCAM array (e.g., the TCAM array 2 of FIG. 2) is illustrated.

A high signal HIGH may be applied to the access transistor (e.g., M1) of the DRAM cell for which data is to be written, and a low signal LOW may be applied to the access transistor (e.g., M11B) of the DRAM cell for which data is not written. For example, as the access transistor M1 is turned on by the high signal HIGH, the storage capacitor C may be charged or discharged based on the voltage input through the bit line BL. Charging of the storage capacitor C to a specific voltage may correspond to a bit value 1, and discharging of the storage capacitor C may correspond to a bit value 0. However, since the relationship between the charging/discharging of the capacitor and the bit value is defined, it may be defined that the storage capacitor C is charged with a specific voltage corresponds to bit value 0, and the storage capacitor C is discharged to bit value 1. After the write operation is completed, the DRAM cell may return to the hold operation.

The refresh operation may be the same or substantially the same as the write operation, except that it is performed in a specific refresh cycle. The refresh cycle may be fixed, but is not limited thereto. If necessary, a refresh operation may be performed at an appropriate time. For example, as described above with reference to FIG. 4, a refresh operation may be performed after the read operation is completed.

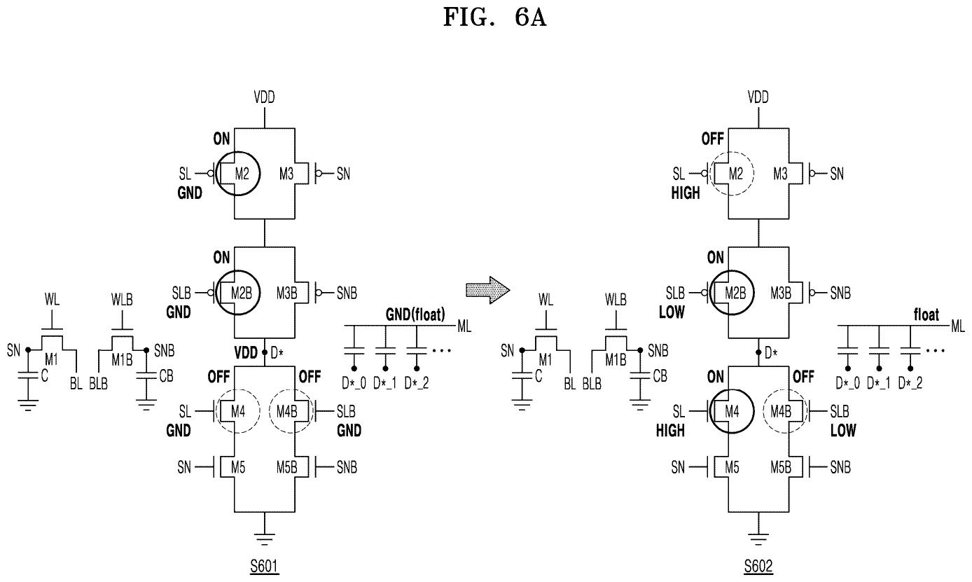

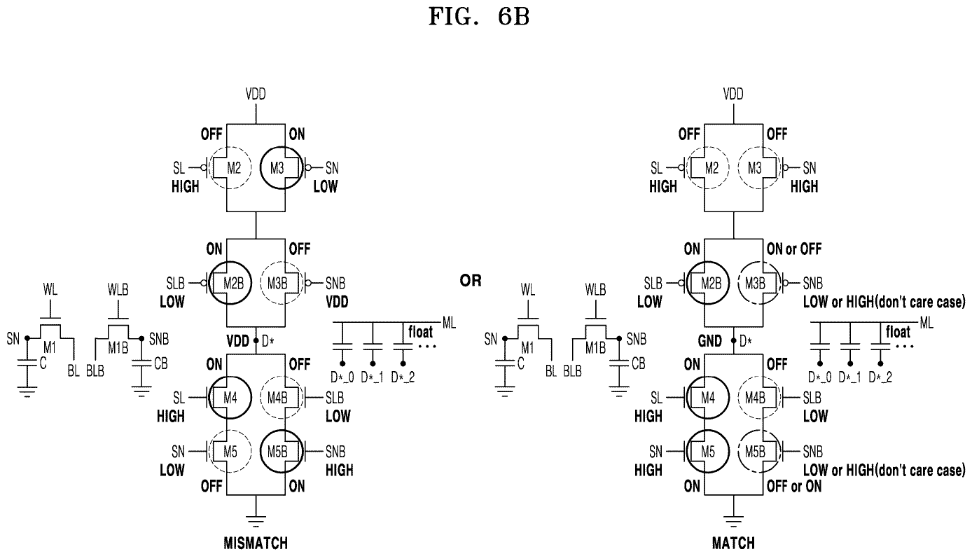

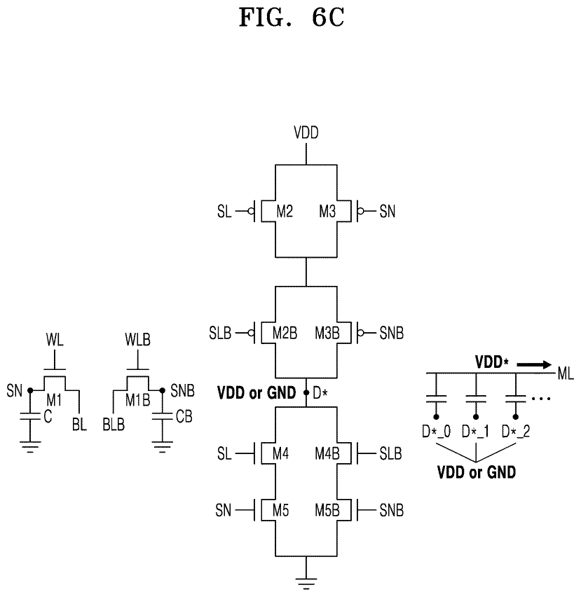

FIGS. 6A to 6C show diagrams for explaining a search operation of a TCAM array according to example embodiments.

Referring to FIGS. 6A to 6C, a process of performing a search operation using a TCAM array (e.g., the TCAM array 2 of FIG. 2) is shown.

Referring to FIG. 6A, in operation S601, a match line ML and select lines SL and SLB may be connected to a ground GND. When the select line SL is connected to the ground GND, the first PMOS transistor M2 may be turned on and the first NMOS transistor M4 may be turned off. In addition, when the select line SLB is connected to the ground GND, the third PMOS transistor M2B may be turned on and the second NMOS transistor M4B may be turned off. Accordingly, the output node D* may be charged with the power supply voltage VDD. After the output node D* is charged with the power supply voltage VDD, the match line ML may be floated.

In operation S602, a high signal HIGH may be applied to one of the select line SL and the select line SLB according to the search data. For example, as illustrated in FIG. 6A, a high signal HIGH may be applied to the select line SL and a low signal LOW may be applied to the select line SLB. The application of the high signal HIGH to the select line SL and the application of the low signal LOW to the select line SLB may correspond to the case of searching for a bit value 1. Conversely, the application of the low signal LOW to the select line SL and the application of the high signal HIGH to the select line SLB may correspond to the case of searching for a bit value 0. However, the relationship between the signal applied to the select line SL or SLB and the search data 0 or 1 may be defined according to a design, and thus, may be defined as opposed to the above-described example.

As shown in FIG. 6A, when a high signal HIGH is applied to the select line SL and a low signal LOW is applied to the select line SLB, the first PMOS transistor M2 and the second NMOS transistor M4B may be turned off, and the third PMOS transistor M2B and the first NMOS transistor M4 may be turned on. In some example embodiments, a voltage of the output node D* may vary according to voltages (e.g., stored data) of the storage nodes SN and SNB.

Referring to FIG. 6B, an example of a case in which search data and stored data match and an example of a case in which search data and stored data do not match are shown.

When the search data is 10 (e.g., SL=HIGH, SLB=LOW), and the stored data is 01 (e.g., SN=LOW, SNB=HIGH), the search data and the stored data mismatch.

When the voltage of the storage node SN is LOW and the voltage of the storage node SNB is HIGH, the second PMOS transistor M3 and the fourth NMOS transistor M5B may be turned on, and the fourth PMOS transistor M3B and the third NMOS transistor M5 may be turned off. In some example embodiments, as shown in the left figure of FIG. 6B, the voltage of the output node D* may be maintained at the power supply voltage VDD.

In contrast, when the search data is 10 (e.g., SL=HIGH, SLB=LOW), and the stored data is 10 (e.g., SN=HIGH, SNB=LOW), the search data and the stored data match. When the voltage of the storage node SN is HIGH, as shown in the right figure of FIG. 6B, the voltage of the output node D* may be discharged to the ground as the third NMOS transistor M5 is turned on.

When the stored data is 11 (e.g., SN=HIGH, SNB=HIGH), the voltage of the output node D* may be discharged to the ground regardless of whether the search data is 10 or 01. In other words, when the stored data is 11 (e.g., SN=HIGH, SNB=HIGH), the search data and the stored data may be considered to match whatever the search data is, and may correspond to the case where the stored data is X (“don't care”).

It has been described above that the case where the data indication is 1 corresponds to the case where the voltage applied to the select line SL or SLB or the storage node SN or SNB is HIGH, but this may be defined in reverse. For example, when the data indication is 0, it may be defined that the voltage applied to the select line SL or SLB or the storage node SN or SNB is HIGH. In addition, data 10 and 01 may be defined as referring to bit values 1 and 0, respectively, and conversely, may be defined as referring to bit values 0 and 1, respectively.

Referring to FIG. 6C, as a determination is made as to whether the search data and the stored data match for each of the plurality of TCAM cells, it may be seen that voltages of output nodes (D*_0, D*_1, D*_2, . . . ) corresponding to each of the plurality of TCAM cells may be determined as VDD or GND.

While the match line ML is floating, as the voltages of the output nodes (D*_0, D*_1, D*_2, . . . ) of the plurality of TCAM cells are redistributed, the voltage level VDD* of the match line ML may be determined in inverse proportion to the number of TCAM cells in which the search data and the stored data match. Being inversely proportional to the number of TCAM cells in which the search data and the stored data match may correspond to being proportional to the number of TCAM cells in which the search data and the stored data mismatch. For example, the voltage level VDD* of the match line ML may be determined by dividing the number of TCAM cells in which the search data and the stored data mismatch by the total number of TCAM cells and multiplying, by VDD, a result of the dividing

$$( = \frac{number of mismathced cells}{number of total cells} VDD ) .$$

In example embodiments, the number of TCAM cells in which the search data and the stored data match may correspond to the number of bits in which the search data and the stored data match.

As described above, the TCAM array (e.g., the TCAM array 2 of FIG. 2) according to the present disclosure may secure integrity of data by using a logic circuit (e.g., the logic circuit 220 of FIG. 2), and may implement a multi-level (e.g., parallel search of multi-bits) by adding a respective output capacitor (one of C₀, C₁, C₂, . . . ) to each TCAM cell (e.g., the TCAM cell 20 of FIG. 2) in order to overcome a limitation of the logic circuit in which only bit unit determination is possible.

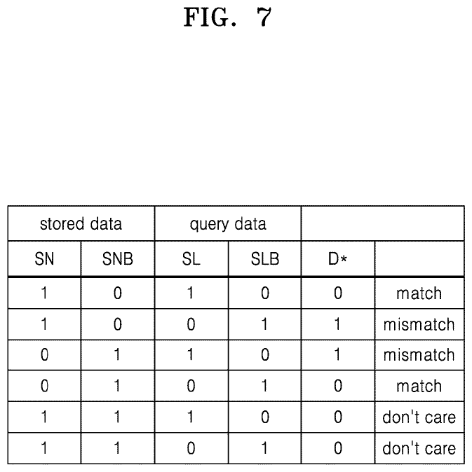

FIG. 7 is a table diagram illustrating a truth table during a search operation of a TCAM array according to example embodiments.

Referring to FIG. 7, a truth table in the search operation of a TCAM array (e.g., the TCAM array 2 in FIG. 2) described with reference to FIGS. 6A to 6C is shown.

Referring to FIG. 7, when the query (or search) data matches the stored data, the voltage of the output node D* becomes 0 (e.g., the discharged state), and when the query (or search) data and the stored data mismatch, the voltage of the output node D* is 1 (e.g., the state in which VDD is charged). In addition, when the stored data is 11, it may be seen that the voltage of the output node (D*) becomes 0 (e.g., discharged) regardless of what the search data is. Therefore, whether the search data and the stored data match may be determined based on the voltage of the output node D*.

However, as described above, depending upon whether a storage node (SN or SNB) is 0 or 1, a state in which the storage capacitor (C or CB) is charged or discharged may vary according to the definition, and depending upon whether a select line (SL or SLB) is 0 or 1, a state in which VDD or GND is applied to the select line (SL or SLB), respectively, may also vary according to the definition.

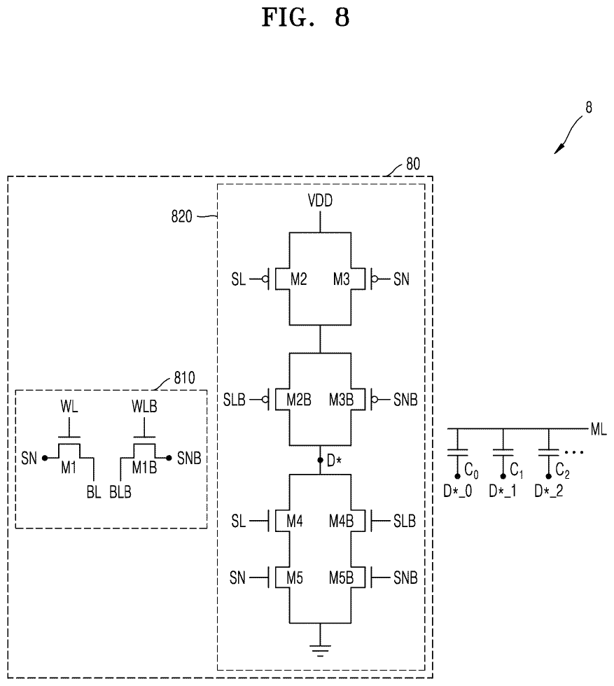

FIG. 8 is a circuit diagram illustrating a configuration of a TCAM array according to example embodiments.

Referring to FIG. 8, a TCAM array 8 may include a plurality of TCAM cells 80, each including two DRAM cells 810 and a logic circuit 820. The TCAM array 8 may be the same or substantially the same as the TCAM array 2 described with reference to FIG. 2, except that the storage capacitor of the two DRAM cells 810 corresponds to the parasitic capacitance of the transistors M3, M3B, M5 and M5B connected to the storage node SN and SNB among the transistors constituting the logic circuit 820. Therefore, the operations of the TCAM array 2 described with reference to FIGS. 3 to 6C may be performed in the same manner by the TCAM array 8 of FIG. 8.

When the two DRAM cells 810 include a first DRAM cell and a second DRAM cell, the storage capacitor of the first DRAM cell may correspond to the parasitic capacitance of the second PMOS transistor M3 and the third NMOS transistor M5, and the storage capacitor of the second DRAM cell may correspond to the parasitic capacitance of the fourth PMOS transistor M3B and the fourth NMOS transistor M5B. When IGZO TFTs having a very low leakage current are employed as the access transistors M1 and M11B, data may be stored using parasitic capacitance of at least some of the transistors included in the logic circuit 820 even if separate storage capacitors C and CB are not provided as shown in FIG. 2. Accordingly, the entire area of the TCAM array 8 may be reduced.

FIG. 9 is a block diagram illustrating a semiconductor memory device according to example embodiments.

Referring to FIG. 9, a semiconductor memory device 90 may include a TCAM array 910 and a peripheral circuit. In the semiconductor memory device 90 illustrated in FIG. 9, only components related to the present example embodiments are illustrated. It will be apparent to those skilled in the art that the semiconductor memory device 90 may include additional components other than those shown in FIG. 9.

The TCAM array 910 may correspond to the TCAM array 2 of FIG. 2 or the TCAM array 8 of FIG. 8. The peripheral circuit may include a row decoder 920, a column driver 930, and a sense amplifier circuit 940. A plurality of TCAM cells may be arranged in the TCAM array 910, and the plurality of TCAM cells may be connected to the row decoder 920 through a plurality of word lines WL or WLB, and may be connected to the sense amplifier circuit 940 through a plurality of bit lines BL or BLB. The plurality of bit lines BL or BLB may be driven by the column driver 930. In an example, the sense amplifier circuit 940 includes a plurality of sense amplifiers, and the plurality of sense amplifiers may be connected to the plurality of bit lines BL or BLB, respectively.

The peripheral circuit may further include a control logic configured to control the row decoder 920, the column driver 930, and the sense amplifier circuit 940. The control logic may control the row decoder 920, the column driver 930, and the sense amplifier circuit 940 based on commands received from a memory controller (not shown). For example, the voltage input to each of the multiple word lines (WL or WLB) by the row decoder 920 and the voltage input to each of the multiple bit lines (BL or BLB) by the column driver 930 vary by the control logic, and write and read operations may be executed accordingly.

Additionally, the peripheral circuit may control the voltage input to the select line (e.g., the select line SL or SLB in FIGS. 2 and 8) to perform the search operation using the logic circuit (e.g., the logic circuit 220 in FIG. 2 or the logic circuit 820 in FIG. 8) included in the TCAM array 910. In this way, the peripheral circuit may control performing the operations of the TCAM array 910 described with reference to FIGS. 3 to 6C.

In some example embodiments, the peripheral circuit may charge the output node (e.g., the output node D* of FIG. 2 or 8) to the power supply voltage VDD by connecting the match line (e.g., the match line ML of FIG. 2 or 8) and the select line to the ground, and then float the match line. Thereafter, the peripheral circuit may determine whether the search data and the stored data match by applying, to the select line, a voltage corresponding to the search data.

When the search data and the stored data mismatch, the voltage of the output node is maintained as the power supply voltage, and when the search data and the stored data match, the voltage of the output node may be discharged to the ground. The peripheral circuit may determine the number of TCAM cells in which the search data and the stored data match based on the voltage level of the match line. The determined number of the TCAM cells may correspond to the number of bits matching between the search data and the stored data. As the voltages of the output nodes of the plurality of TCAM cells are redistributed while the match line is floated, the voltage level of the match line may be determined in inverse proportion to the number of the TCAM cells in which the search data and the stored data match. However, example embodiments are not necessarily limited thereto, and depending on the definition, the voltage level of the match line may be determined in proportion to the number of TCAM cells whose search data and stored data match.

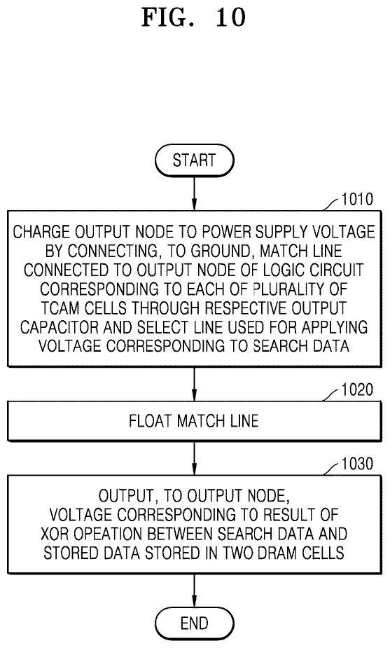

FIG. 10 is a flowchart illustrating an operating method of a semiconductor memory device according to example embodiments.

Referring to FIG. 10, a method of operating a semiconductor memory device according to the present disclosure includes operations processed by the semiconductor memory device 90 of FIG. 9. Therefore, even if it is omitted below, it may be seen that the above description of FIG. 9 also applies to the method of operating the semiconductor memory device of FIG. 10. For example, the semiconductor memory device may include a TCAM array (e.g., the TCAM array 910 in FIG. 9), including a plurality of TCAM cells each including two DRAM cells (e.g., DRAM cells 210 in FIG. 2 or DRAM cells 810 in FIG. 8) and a logic circuit (e.g., the logic circuit 220 in FIG. 2 or the logic circuit 820 in FIG. 8), and a peripheral circuit (e.g., the row decoder 920, the column driver 930, and the sense amplifier circuit 940 in FIG. 9) for controlling the operation of the TCAM array.

In operation 1010, the semiconductor memory device may charge an output node to a power supply voltage by connecting, to the ground, a match line connected to an output node of a logic circuit corresponding to each of the plurality of TCAM cells through a respective output capacitor, and a select line used to apply a voltage corresponding to the search data.

In operation 1020, the semiconductor memory device may float the match line.

In operation 1030, the semiconductor memory device may output, to the output node, a voltage corresponding to a result of the XOR operation between the search data and the stored data stored in the two DRAM cells by applying, to the select line, a voltage corresponding to the search data.

When the search data and the stored data mismatch, the voltage of the output node is maintained as the power supply voltage, and when the search data and the stored data match, the voltage of the output node may be discharged to the ground. The semiconductor memory device may determine, based on the voltage level of the match line, the number of TCAM cells in which the search data and the stored data match. In example embodiments, the determined number of the TCAM cells may correspond to the number of bits matching between the search data and the stored data.

According to some example embodiments, as the voltages of the output nodes of the plurality of TCAM cells are redistributed while the match line is floated, the voltage level of the match line may be determined in inverse proportion to the number of the TCAM cells in which the search data and the stored data match.

As described above, the semiconductor memory device according to the present disclosure may include a lower-cost lower-power TCAM array that supports a higher-speed parallel operation while ensuring data integrity, and thus may be suitable for use in an AI-oriented device.

As described above, the method of operating the semiconductor memory device may be recorded on a computer-readable recording medium in which one or more programs including instructions executing the method are recorded. Examples of computer-readable recording media include magnetic media such as hard disks, floppy disks and magnetic tapes, optical media such as CD-ROMs and DVDs, magneto-optical media such as floptical disks, and hardware devices such as ROMs, RAMs, and flash memories, specifically configured to store and execute program instructions. Examples of program instructions include machine language codes, such as those made by compilers, as well as advanced language codes that may be executed by computers using interpreters or the like.

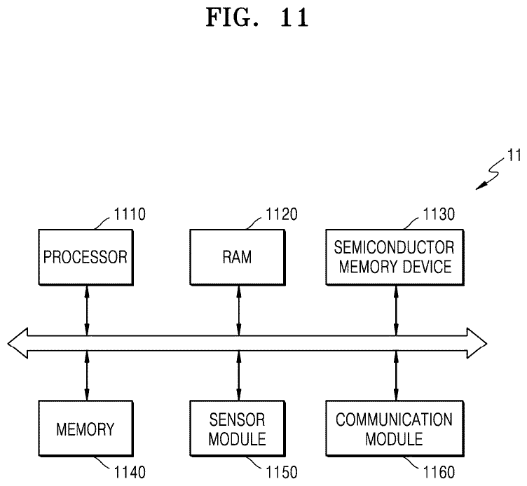

FIG. 11 is a block diagram illustrating a configuration of an electronic system according to example embodiments.

Referring to FIG. 11, an electronic system 11 may include a processor 1110, a random-access memory (RAM) 1120, a semiconductor memory device 1130, a memory 1140, a sensor module 1150, and a communication module 1160. The electronic system 11 may further include an input/output module, a security module, a power control device, and the like. Some of the hardware components of the electronic system 11 may be mounted on at least one semiconductor chip. The electronic system 11 may be applied to a robot device such as a drone, an advanced driver assistance system (ADAS), or the like, a smart TV, a smartphone, a medical device, a mobile device, an image display device, a measurement device, and an IoT device, and the like, and may be mounted on at least one of various types of electronic devices.

The processor 1110 controls the overall operation of the electronic system 11. The processor 1110 may include a processor core (e.g., single core) or a plurality of processor cores (e.g., multi-core). The processor 1110 may process or execute programs and/or data stored in the memory 1140. In some example embodiments, the processor 1110 may control the function of the semiconductor memory device 1130 by executing programs stored in the memory 1140. The processor 1110 may be implemented as a central processing unit (CPU), a graphics processing unit (GPU), a neural processing unit (NPU), a micro controller unit (MCU), an application processor (AP), and the like.

The RAM 1120 may temporarily store programs, data, or instructions. For example, programs and/or data stored in the memory 1140 may be temporarily stored in the RAM 1120 according to the control or boot code of the processor 1110. The RAM 1120 may be implemented as a memory such as dynamic RAM (DRAM), static RAM (SRAM), or the like.

The semiconductor memory device 1130 may correspond to the semiconductor memory device 90 described with reference to FIG. 9. The semiconductor memory device 1130 may be configured to process data search and comparison operations in parallel under the control of the processor 1110. The semiconductor memory device 1130 may perform nearest neighbor search, distance calculation, and the like between data vectors by performing a parallel search operation at low power. In addition, the semiconductor memory device 1130 is applicable to various machine learning or deep learning including one-shot learning. The semiconductor memory device 1130 is suitable for storing a lot of data even in a limited area, and may be suitable for AI-oriented TCAM applications because it is possible to search for a lot of data at higher speed.

The memory 1140 is a storage place for storing data and may store an operating system (OS), various programs, and various pieces of data. In some example embodiments, the memory 1140 may store intermediate results generated during the operation of the semiconductor memory device 1130.

The memory 1140 may be a DRAM, but is not limited thereto. The memory 1140 may include at least one of a volatile memory and a nonvolatile memory. The nonvolatile memory includes read-only memory (ROM), programmable ROM (PROM), electrically programmable ROM (EPROM), electrically erasable and programmable ROM (EEPROM), flash memory, phase-change ROM (PROM), magnetic ROM (MROM), resistive ROM (RROM), ferroelectric ROM (FROM), and the like. The volatile memory includes dynamic RAM (DRAM), static RAM (SRAM), synchronous DRAM (SDRAM), phase-change RAM (PRAM), magnetic RAM (MRAM), resistive RAM (RRAM), and ferroelectric RAM (FeRAM). In some example embodiments, the memory 1140 may include at least one of a hard disk drive (HDD), a solid state drive (SSD), a compact flash (CF), a secure digital (SD), a micro secure digital (Micro-SD), a mini secure digital (Mini-SD), and a memory stick.

The sensor module 1150 may collect information around the electronic device on which the electronic system 11 is mounted. The sensor module 1150 may sense or receive a signal (e.g., an image signal, a voice signal, a magnetic signal, a bio signal, a touch signal, etc.) from the outside of the electronic device and convert the sensed or received signal into data. To this end, the sensor module 1150 may include at least one of various types of sensing devices such as a sensing device, for example, a microphone, an imaging device, an image sensor, a light detection and ranging (LIDAR) sensor, an ultrasonic sensor, an infrared sensor, a biosensor, and a touch sensor.

The sensor module 1150 may provide the converted data to the semiconductor memory device 1130 as input data. For example, the sensor module 1150 may include an image sensor, generate a video stream by photographing an external environment of the electronic device, and sequentially provide the continuous data frame of the video stream to the semiconductor memory device 1130 as input data. However, example embodiments are not limited thereto, and the sensor module 1150 may provide various types of data to the semiconductor memory device 1130.

The communication module 1160 may include various wired or wireless interfaces capable of communicating with an external device. For example, the communication module 1160 may include a communication interface, which may be connect to a wired local area network (LAN), a wireless local area network (WLAN) such as wireless fidelity (Wi-fi), a wireless personal area network (WPAN) such as Bluetooth, a wireless universal serial bus (USB), Zigbee, near field communication (NFC), radio-frequency identification (RFID), power line communication (PLC), or a mobile cellular network such as 3rd generation (3G), 4th generation (4G), or long term evolution (LTE).

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor memory device comprising:
a ternary content-addressable memory (TCAM) array including a plurality of TCAM cells each including two dynamic random-access memory (DRAM) cells and a logic circuit; and
a peripheral circuit configured to control an operation of the TCAM array, wherein
each of the two DRAM cells includes an access transistor including a gate connected to a word line, a drain connected to a bit line, and a source connected to a storage node, and a storage capacitor connected to the storage node, wherein
the logic circuit is configured to operate in response to a power supply voltage and to output, to an output node, a voltage corresponding to a result of an exclusive OR (XOR) operation between search data corresponding to a voltage applied to a select line and stored data stored in the storage capacitor, and
the output node of each of the plurality of TCAM cells is connected to a match line through a respective output capacitor.

2. The semiconductor memory device of claim 1, wherein the peripheral circuit is further configured to:
charge the output node with the power supply voltage by connecting the match line and the select line to a ground and then float the match line, and
determine whether the search data and the stored data match by applying a voltage corresponding to the search data to the select line.

3. The semiconductor memory device of claim 2, wherein,
when the search data and the stored data mismatch, the voltage of the output node is maintained as the power supply voltage, and
when the search data and the stored data match, the voltage of the output node is discharged to ground.

4. The semiconductor memory device of claim 2, wherein the peripheral circuit is further configured to:
determine a number of the TCAM cells in which the search data and the stored data match based on a voltage level of the match line, wherein
the determined number of the TCAM cells corresponds to a number of matching bits between the search data and the stored data.

5. The semiconductor memory device of claim 4, wherein as the voltages of the output nodes of the plurality of TCAM cells are redistributed while the match line is floated, the voltage level of the match line is determined in inverse proportion to the number of the TCAM cells in which the search data and the stored data match.

6. The semiconductor memory device of claim 1, wherein the logic circuit comprises
first to fourth P-type metal-oxide-semiconductor (PMOS) transistors and first to fourth N-type metal-oxide-semiconductor (NMOS) transistors, wherein
sources of the first PMOS transistor and the second PMOS transistor are connected to the power supply voltage,
drains of the first PMOS transistor and the second PMOS transistor are connected to sources of the third PMOS transistor and the fourth PMOS transistor,
drains of the third PMOS transistor and the fourth PMOS transistor, and drains of the first NMOS transistor and the second NMOS transistor are connected to the output node,
a source of the first NMOS transistor is connected to a drain of the third NMOS transistor, a source of the second NMOS transistor is connected to a drain of the fourth NMOS transistor, and
sources of the third NMOS transistor and the fourth NMOS transistor are connected to the ground.

7. The semiconductor memory device of claim 6, wherein
the two DRAM cells include a first DRAM cell and a second DRAM cell,
gates of the first PMOS transistor and the first NMOS transistor are connected to a first select line of the first DRAM cell,
gates of the second PMOS transistor and the third NMOS transistor are connected to a first storage node of the first DRAM cell,
gates of the third PMOS transistor and the second NMOS transistor are connected to a second select line of the second DRAM cell, and
gates of the fourth PMOS transistor and the fourth NMOS transistor are connected to a second storage node of the second DRAM cell.

8. The semiconductor memory device of claim 1, wherein the access transistor comprises an indium gallium zinc oxide (IGZO) thin film transistor (TFT).

9. The semiconductor memory device of claim 1, wherein the storage capacitor comprises a capacitor connected between the storage node and ground.

10. The semiconductor memory device of claim 1, wherein the storage capacitor corresponds to a parasitic capacitance of transistors connected to the storage node, among transistors constituting the logic circuit.

11. An operating method of a semiconductor memory device, wherein the semiconductor memory device comprises
a ternary content-addressable memory (TCAM) array including a plurality of TCAM cells each including two dynamic random-access memory (DRAM) cells and a logic circuit, and a peripheral circuit configured to control an operation of the TCAM array,
the operating method comprising:
charging an output node with a power supply voltage by connecting, to ground, a match line connected to the output node of the logic circuit corresponding to each of the plurality of TCAM cells through a respective output capacitor and a select line used to apply a voltage corresponding to search data,
floating the match line; and
by applying the voltage corresponding to the search data to the select line, outputting, to the output node, a voltage corresponding to a result of an exclusive OR (XOR) operation between the search data and stored data stored in the two DRAM cells.

12. The operating method of claim 11, wherein,
when the search data and the stored data are mismatched, the voltage of the output node is maintained as the power supply voltage, and
when the search data and the stored data match, the voltage of the output node is discharged to the ground.

13. The operating method of claim 11, further comprising
determining a number of the TCAM cells in which the search data and the stored data match based on a voltage level of the match line, wherein
the determined number of the TCAM cells corresponds to a number of matching bits between the search data and the stored data.

14. The operating method of claim 13, wherein, as the voltages of the output nodes of the plurality of TCAM cells are redistributed while the match line is floated, the voltage level of the match line is determined in inverse proportion to the number of the TCAM cells in which the search data and the stored data match.

15. The operating method of claim 11, wherein the logic circuit comprises
first to fourth PMOS transistors and first to fourth NMOS transistors, wherein
sources of the first PMOS transistor and the second PMOS transistor are connected to the power supply voltage,
drains of the first PMOS transistor and the second PMOS transistor are connected to sources of the third PMOS transistor and the fourth PMOS transistor,
drains of the third PMOS transistor and the fourth PMOS transistor, and drains of the first NMOS transistor and the second NMOS transistor are connected to the output node,
a source of the first NMOS transistor is connected to a drain of the third NMOS transistor, a source of the second NMOS transistor is connected to a drain of the fourth NMOS transistor, and
sources of the third NMOS transistor and the fourth NMOS transistor are connected to the ground.

16. The operating method of claim 15, wherein
the two DRAM cells comprise a first DRAM cell and a second DRAM cell,
gates of the first PMOS transistor and the first NMOS transistor are connected to a first select line of the first DRAM cell,
gates of the second PMOS transistor and the third NMOS transistor are connected to a first storage node of the first DRAM cell,
gates of the third PMOS transistor and the second NMOS transistor are connected to a second select line of the second DRAM cell, and
gates of the fourth PMOS transistor and the fourth NMOS transistor are connected to a second storage node of the second DRAM cell.

17. The operating method of claim 11, wherein
each of the two DRAM cells comprises an access transistor including a gate connected to a word line, a drain connected to a bit line, and a source connected to a storage node, and a storage capacitor connected to the storage node, wherein
the access transistor comprises an IGZO TFT.

18. The operating method of claim 17, wherein the storage capacitor comprises a capacitor connected between the storage node and the ground.

19. The operating method of claim 17, wherein the storage capacitor corresponds to a parasitic capacitance of transistors connected to the storage node, among transistors constituting the logic circuit.

20. An electronic system comprising:
a semiconductor memory device; and
a processor configured to process data search and comparison operations in parallel using the semiconductor memory device, wherein
the semiconductor memory device comprises
a ternary content-addressable memory (TCAM) array including a plurality of TCAM cells each including two dynamic random-access memory (DRAM) cells and a logic circuit, and
a peripheral circuit configured to control an operation of the TCAM array, wherein
each of the two DRAM cells comprises an access transistor including a gate connected to a word line, a drain connected to a bit line, and a source connected to a storage node, and a storage capacitor connected to the storage node, wherein
the logic circuit is configured to operate in response to a power supply voltage and output, to an output node, a voltage corresponding to a result of an exclusive OR (XOR) operation between search data corresponding to a voltage applied to a select line and stored data stored in the storage capacitor,
the output node of each of the plurality of TCAM cells is connected to a match line through a respective output capacitor, and
a voltage level of the match line is related to a number of matching bits between the search data and the stored data.
